(19) United States
(12) Patent Application Publication
(10) Pub. No.: US 2009/0161291 A1
(43) Pub. Date: Jun. 25, 2009

(54) Capacitor for Semiconductor Device and Method of Manufacturing the Same

(76) Inventor: Sang Kwon KIM, Suwon-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/336,511

(22) Filed: Dec. 16, 2008

(30) Foreign Application Priority Data
Dec. 24, 2007 (KR) 10-2007-0136552

(51) Int. Cl. H01G 4/008; H01L 21/336

(52) U.S. Cl. 361/305; 438/393; 257/E21.013

(57) ABSTRACT

Provided is a capacitor for a semiconductor device. The capacitor comprises a bottom electrode, a dielectric pattern, and a top electrode. The bottom electrode has an uneven surface. The dielectric pattern is on the bottom electrode, and the top electrode is on the dielectric pattern. The bottom electrode has a first height in edge and center regions thereof, and a protrusion between the edge region and the center region of the bottom electrode having a second height greater than the first height.

### CROSS-REFERENCE TO RELATED APPLICATIONS

The present application claims priority under 35 U.S.C. 119 to Korean Patent Application No. 10-2007-0136552 (filed on Dec. 24, 2007), which is hereby incorporated by reference in its entirety.

### BACKGROUND

In semiconductor integrated circuits, various devices including a transistor, a capacitor, and a resistor may be integrated on a single chip. Various methods of effectively forming these devices have been developed. For capacitors used in analog logic circuits, a polysilicon-insulator-polysilicon (PIP) structure or a metal-insulator-metal (MIM) structure is mainly adopted. Among these, a PIP capacitor having the PIP structure is widely used for modulating frequency and preventing noise of an analog device. Since a bottom electrode and a top electrode of the PIP capacitor are formed of polysilicon that is also used as a material for a gate electrode in a logic transistor, the electrode of the PIP capacitor can be simultaneously manufactured when the gate electrode is manufactured, without an additional process.

The capacity of a PIP capacitor in a semiconductor device is determined based on the area of the dielectric between the bottom electrode and the top electrode.

### SUMMARY

Embodiments of the present invention provide a capacitor and a method of manufacturing the same, which is adapted to increase the capacity of the capacitor in a PIP structure with a small line width.

In one embodiment, a capacitor comprises: a bottom electrode having an uneven surface on a semiconductor substrate; a dielectric pattern on the bottom electrode; and a top electrode on the dielectric pattern, wherein the bottom electrode has a first height in an edge and a center thereof, and comprises at least one protrusion between the edge and the center of the bottom electrode, the protrusion having a second height greater than the first height.

In another embodiment of the present invention, a method of manufacturing a capacitor comprises: forming a first polysilicon layer on a semiconductor substrate; patterning and selectively etching the first polysilicon layer to form a bottom electrode having an uneven surface; and forming a dielectric pattern and a top electrode on the bottom electrode, wherein the bottom electrode has a first height in an edge region and a center region of the uneven surface, and at least one protrusion between the edge and the center regions of the bottom electrode having a second height greater than the first height.

The details of one or more embodiments are set forth in the accompanying drawings and the description below. Other features will be apparent from the description and drawings, and from the claims.

### BRIEF DESCRIPTION OF THE DRAWINGS

FIGS. 1 to 6 are cross-sectional views illustrating a method of manufacturing a capacitor for a semiconductor device according to an exemplary embodiment of the present invention.

### DETAILED DESCRIPTION OF THE EMBODIMENTS

Hereinafter, a capacitor for a semiconductor device and a method of manufacturing the same according to embodiments of the invention will now be described in detail with reference to the accompanying drawings.

In the description of various embodiments, it will be understood that when a layer (or film) is referred to as being ‘on’ another layer or substrate, it can be directly on another layer or substrate, or one or more intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it may be the only layer between the two layers, or one or more intervening layers may also be present.

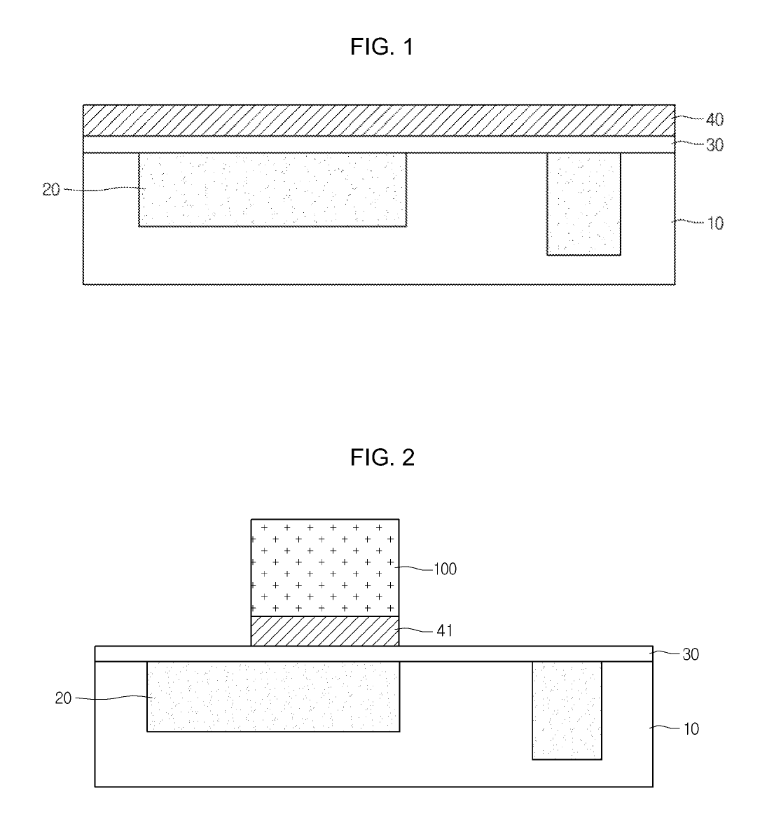

FIGS. 1 to 6 are cross-sectional views illustrating a method of manufacturing a capacitor of a semiconductor device according to exemplary embodiments of the present invention.

Referring to FIG. 1, a first polysilicon layer 40 is formed on a semiconductor substrate 10 (e.g., by chemical vapor deposition [PE, PA]). In some embodiments, the substrate 10 may comprise a single crystal silicon substrate (e.g., a wafer), which may have one or more layers of Si, strained Si, or SiGe thereon (e.g., epitaxial Si and/or SiGe).

The semiconductor substrate 10 may include a device isolation region 20 defining both an active region and a field region. The device isolation region 20 may be formed by selectively patterning and etching the semiconductor substrate 10 to form a trench and then depositing an insulating layer (e.g., silicon dioxide) into the trench. The polysilicon layer 40 may have a thickness ranging from about 2000 Å to about 3000 Å on the semiconductor substrate 10. For example, in one exemplary embodiment, the polysilicon layer 40 may have a thickness of about 2600 Å.

Also, before forming the polysilicon layer 40, a thin oxide layer (e.g., silicon dioxide) 30 may be formed on the semiconductor substrate 10 by thermal oxidation or CVD and densification.

Referring to FIG. 2, a first polysilicon pattern 41 is formed on the semiconductor substrate 10. The first polysilicon pattern 41 may be formed by patterning the polysilicon layer 40. Specifically, to form the first polysilicon pattern 41, a first photoresist pattern 100 is formed on the polysilicon layer 40. The first photoresist pattern 100 may be selectively formed by applying a photoresist and then by performing an exposure process and a development process. Then, the polysilicon layer 40 is etched using the first photoresist pattern 100 as an etch mask to form the first polysilicon pattern 41. At this point, the oxide layer 30 may also be etched.

Although not shown in FIG. 2, when the first polysilicon pattern 41 is formed, other devices including a resistor and/or a gate electrode may be simultaneously formed on the semiconductor substrate 10 with the polysilicon layer 40.

After that, the first photoresist pattern 100 may be removed through an ashing process, or any other process known in the art for removing photoresist patterns.

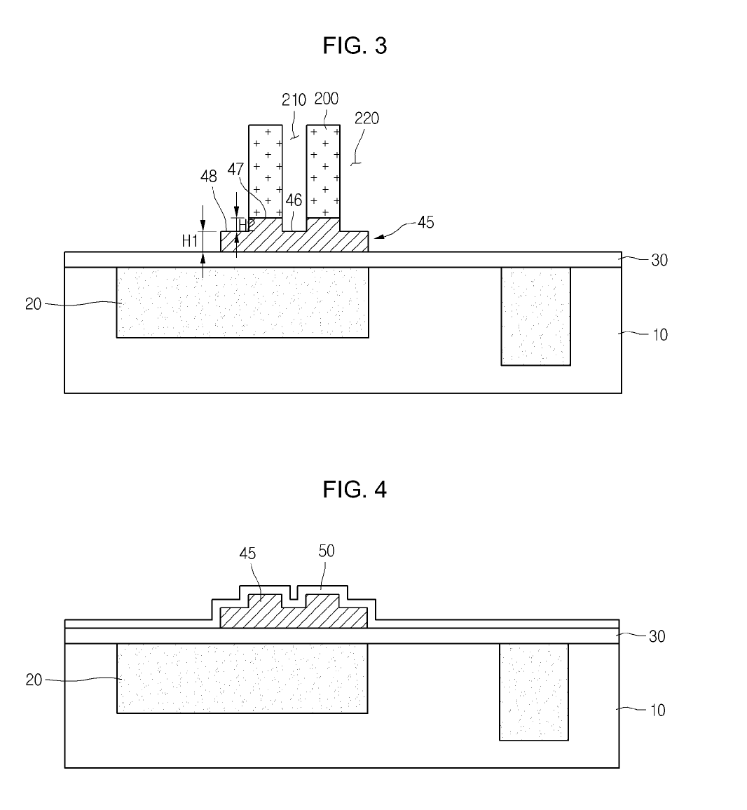

Referring to FIG. 3, a bottom electrode 45 is formed on the semiconductor substrate 10. In exemplary embodiments, the bottom electrode 45 may be formed by patterning the first polysilicon pattern 41.

For example, to form the bottom electrode 45, a second photoresist pattern 200 is formed on the first polysilicon pattern 41. The second photoresist pattern 200 may be selectively formed by applying a photoresist and then by performing an exposure process and a development process. The second photoresist pattern 200 generally includes a first exposing portion 210 exposing a center of the first polysilicon pattern 41, and a second exposing portion 220 selectively exposing at least one edge (and preferably all edges) of the first polysilicon pattern 41.

The first polysilicon pattern 41 is etched using the second photoresist pattern 200 as an etch mask. As a result of the etching process, the center of the first polysilicon pattern 41 is selectively removed through the first exposing portion 210 of the second photoresist pattern 200, and the edge of the first polysilicon pattern 41 is selectively removed through the second exposing portion 220 of the second photoresist pattern 200. At this point, the etching for the first polysilicon pattern 41 may be controlled to prevent the entire first polysilicon pattern 41 from being removed. An etch depth may be from 500 to 2000 Å, or from 20 to 80% of the thickness of the polysilicon layer 40. Alternately, the layer patterning and partial etching/protrusion-forming steps may be reversed.

Thus, the first polysilicon pattern 41 is selectively and partially removed to form the bottom electrode 45. As a result, a surface of the bottom electrode 45 may have different heights. For example, referring again to FIG. 3, in the bottom electrode 45, protrusions 47 that were covered by the second photoresist pattern 200 during the etching step have a second height H2 that is equal to the thickness of the first polysilicon pattern 41 prior to the etching step. In addition, a center 46 and an edge 48 of the bottom electrode 45, which were exposed through (i.e., not covered by) the second photoresist pattern 200 during the etching step, may have a first height H1 that is smaller than the thickness of the first polysilicon pattern 41 as deposited.

For example, in the bottom electrode 45, the first height H1 of the center 46 and the edge 48 may range from about 1000 Å to about 2500 Å, and the second height H2 of the protrusions 47 between the center 46 and the edge 48 may range from about 2000 Å to about 3000 Å. Thus, even when a width of the first polysilicon pattern 41 is narrow, the area of the bottom electrode 45 may be increased by forming the uneven surface.

Referring to FIG. 4, a dielectric 50 is formed on the semiconductor substrate 10 with the bottom electrode 45. The dielectric 50 may include an insulating layer. The dielectric 50 may comprise a stacked structure, and may be formed by stacking high temperature oxide (HTO), SiN and SiO₂ layers. For example, the HTO layer (which may comprise or consist of a thermal oxide) may have a thickness of about 50 Å, the SiN layer may have a thickness of about 60 Å, and the SiO₂ layer may have a thickness of about 300 Å.

Since the dielectric 50 is generally formed on the entire surface of the semiconductor substrate 10, the dielectric 50 may be in “face-to-face” contact with the center 46, the edge 48, and the protrusions 47 of the bottom electrode 45. Thus, the dielectric 50 may be formed along the uneven surface of the bottom electrode 45, thereby increasing a contact area between the bottom electrode 45 and the dielectric 50. That is, a surface area of the dielectric 50 may be expanded.

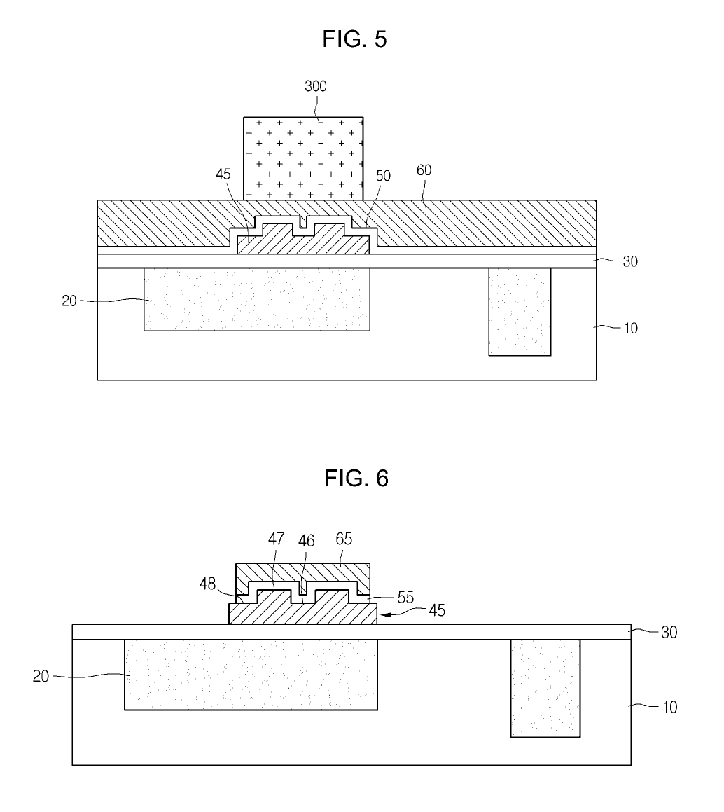

Referring now to FIG. 5, a second polysilicon layer 60 is formed on the dielectric 50. The second polysilicon layer 60 is formed on the entire surface of the dielectric 50. The second polysilicon layer 60 may have a thickness ranging from about 1000 Å to 2000 Å. When the second polysilicon layer 60 is deposited, a phosphorus (P) or other conventional doping process may additionally be performed.

Referring to FIG. 6, a dielectric pattern 55 and a top electrode 65 are formed on the bottom electrode 45. The dielectric pattern 55 and the top electrode 65 may be formed by patterning the dielectric 50 and the second polysilicon layer 60.

Referring again to FIG. 5, to form the dielectric pattern 55 and the top electrode 65, a third photoresist pattern 300 is formed on the second polysilicon layer 60. The third photoresist pattern 300 may have the same area or a smaller area than that of the first photoresist pattern 100. In the alternative, the third photoresist pattern 300 may have a greater area. This increases capacitance, but does not increase the area of the capacitor.

The second polysilicon layer 60 and the dielectric 50 are then etched using the third photoresist pattern 300 as an etch mask, to form the top electrode 65 and the dielectric pattern 55, as shown in FIG. 6. Although not shown, other devices including a resistor and a gate may also be formed when patterning the second polysilicon layer 60.

As illustrated in FIG. 6, the present capacitor includes the bottom electrode 45 having the uneven surface on the semiconductor substrate 10, the dielectric pattern 55 on the bottom electrode 45, and the top electrode 65 on the dielectric pattern 55. The edge region 48 and the center region 46 of the bottom electrode 45 have the first height H1, and the protrusions 47, between the edge region 48 and the center region 46, have the second height H2 greater than the first height H1.

In exemplary embodiments, the bottom electrode 45 and the top electrode 65 comprise (doped) polysilicon, and the dielectric pattern 55 is between the bottom electrode 45 and the top electrode 65, to form a capacitor having a PIP structure. The dielectric pattern 55 may comprise at least one of HTO, SiN, and SiO₂ or a laminate thereof (e.g., SiO₂/SiN, SiO₂/SiN/SiO₂, or HTO/SiN/SiO₂).

As described above, in the present capacitor of the disclosure, the bottom electrode has an uneven surface to expand the contact area between the dielectric pattern and the bottom electrode, thereby increasing the capacitance of the capacitor.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A capacitor of a semiconductor device comprising:
a bottom electrode having an uneven surface on a semiconductor substrate, wherein the bottom electrode has a first height in an edge region and a center region, and at least one protrusion between the edge region and the center region having a second height greater than the first height;
a dielectric pattern on the bottom electrode; and
a top electrode on the dielectric pattern.

2. The capacitor according to claim 1, wherein the bottom electrode and the top electrode comprise polysilicon.

3. The capacitor according to claim 1, wherein the dielectric pattern comprises a laminate.

4. The capacitor according to claim 3, wherein the laminate comprises at least one of a high temperature oxide, SiN, and SiO₂.

5. The capacitor according to claim 1, comprising first and second protrusions.

6. The capacitor according to claim 1, wherein the substrate comprises a device isolation region defining an active region and a field region.

7. The capacitor according to claim 1, wherein the second height is from about 2000 Å to 3000 Å.

8. The capacitor according to claim 7, wherein the first height is from about 1000 Å to 2500 Å.

9. The capacitor according to claim 1, wherein the top electrode has a thickness of from about 1000 Å to 2000 Å.

10. The capacitor according to claim 1, wherein the top electrode comprises polysilicon doped with phosphorus.

11. A method of manufacturing a capacitor of a semiconductor device comprising:
forming a first polysilicon layer on a semiconductor substrate;
patterning and selectively etching the first polysilicon layer to form
a bottom electrode having an uneven surface, wherein the bottom electrode has a first height in an edge region and a center region, and at least one protrusion between the edge region and the center region having a second height greater than the first height; and
forming a dielectric pattern and a top electrode on the bottom electrode.

12. The method according to claim 11, wherein the bottom electrode comprises first and second protrusions.

13. The method according to claim 11, wherein forming the bottom electrode comprises:
forming a first photoresist pattern on the first polysilicon pattern, the first photoresist pattern exposing a center and an edge of the first polysilicon pattern;
selectively etching the first polysilicon pattern exposed through the first photoresist pattern to form the edge and the center that have the first height; and
forming the first and second protrusions between the edge and the center, the first and second protrusions having a second thickness that is the same as a thickness of the first polysilicon pattern.

14. The method according to claim 11, wherein forming the dielectric pattern and the top electrode comprises:
forming a dielectric on the semiconductor substrate with the bottom electrode;
forming a second polysilicon layer on the dielectric;
forming a photoresist pattern on the second polysilicon layer corresponding to the bottom electrode; and
etching the second polysilicon layer and the dielectric using the photoresist pattern as an etch mask.

15. The method according to claim 11, wherein the dielectric pattern comprises at least one of a high temperature oxide layer, a SiN layer, and a SiO₂ layer.

16. The method according to claim 15, further comprising forming a device isolation region by selectively patterning and etching the semiconductor substrate to form a trench, and depositing an insulating layer into the trench, the device isolation region defining an active region and a field region.

17. The method according to claim 11, wherein the second height is from about 2000 Å to 3000 Å.

18. The method according to claim 11, wherein the first height is from about 1000 Å to 2500 Å.

19. The method according to claim 11, wherein the top electrode has a thickness of from about 1000 Å to 2000 Å.

20. A method of manufacturing a capacitor of a semiconductor device comprising:
forming a first polysilicon layer on a semiconductor substrate;
patterning the first polysilicon layer to form a first polysilicon pattern;
selectively etching the first polysilicon pattern to form a bottom electrode having an uneven surface, wherein the bottom electrode has a first height in an edge region and a center region, and at least one protrusion between the edge and the center having a second height greater than the first height;
forming a dielectric pattern on the bottom electrode; and
forming a top electrode on the dielectric pattern.
